(19) United States
(12) Patent Application Publication
(10) Pub. No.: US 2012/0088370 A1
(43) Pub. Date: Apr. 12, 2012

(54) Substrate Processing System with Multiple Processing Devices Deployed in Shared Ambient Environment and Associated Methods

(75) Inventors: David J. Hemker, San Jose, CA (US); Lubab L. Sheet, Mountain View, CA (US); Jeffrey Marks, Saratoga, CA (US)

(73) Assignee: Lam Research Corporation, Fremont, CA (US)

(21) Appl. No.: 12/899,503

(22) Filed: Oct. 6, 2010

(51) Int. Cl. H01L 21/302; H01L 21/306; B05B 13/02; C23C 16/00

(52) U.S. Cl. 438/704; 118/723 R; 156/345.51; 156/345.21; 118/324; 156/345.23; 118/729; 118/500; 257/E21.214

(57) ABSTRACT

A plurality of substrate processing devices are disposed in a separated manner within a shared ambient environment. A conveyance device is disposed within the shared ambient environment and is defined to move a substrate through and between each of the substrate processing devices in a continuous manner. Some substrate processing devices are defined to perform dry substrate processing operations in which an energized reactive environment is created in exposure to the substrate in an absence of liquid material. Some substrate processing devices are defined to perform wet substrate processing operations in which at least one material in a liquid state is applied to the substrate. In one embodiment, a complementary pair of dry and wet substrate processing devices are disposed in the shared ambient environment in a sequential manner relative to movement of the substrate by the conveyance device.

### BACKGROUND OF THE INVENTION

In semiconductor device fabrication, materials are built-up in a layered manner on a substrate, i.e., silicon wafer, to form integrated circuit devices. The build-up of materials in the layered manner can include many different types of fabrication operations that deposit material, remove material, modify material, or combinations thereof. Conventionally, most semiconductor device fabrication processes are conducted in chambers that are specially designed to perform the respective fabrication process. Therefore, it is most often necessary for a given substrate to be moved from one isolated processing chamber to another isolated processing chamber to have different types of fabrication processes performed thereon. Such movement of the substrate from chamber-to-chamber requires time and adds expense to the overall fabrication cost of the final substrate.

For example, in some semiconductor fabrication processes a photoresist material is disposed on the substrate, patterned, and used as a mask for either a material deposition, removal, or modification process. During some processes, such as ion implant processes, the exposed photoresist material can be transformed into a cross-linked photoresist crust material that is extremely difficult to remove using a single wet stripping process. In this case, it is necessary for the cross-linked photoresist crust and the underlying normal photoresist material to be subjected to different processes for their respective removal from the substrate. Conventionally, these different required photoresist removal processes must be performed in separate isolated chambers, which requires transfer of the substrate from chamber-to-chamber. Again, transfer of the substrate from chamber-to-chamber for multiple sequential processing adds time and expense to the overall fabrication cost of the final substrate, and increases the probability that a given substrate will be damaged during the chamber-to-chamber movement operation.

It is within this context that the invention disclosed herein arises.

### SUMMARY OF THE INVENTION

In one embodiment, a substrate processing system is disclosed. The system includes a plurality of substrate processing devices disposed in a separated manner within a shared ambient environment. The system also includes a conveyance device disposed within the shared ambient environment and defined to move a substrate through and between each of the plurality of substrate processing devices in a continuous manner.

In another embodiment, a substrate processing system is disclosed. The system includes a first substrate processing device disposed within a shared ambient environment. The system also includes a second substrate processing device disposed within the shared ambient environment and separate from the first substrate processing device. The system further includes a conveyance device disposed within the shared ambient environment and defined to move a substrate in a continuous manner through the first substrate processing device, between the first and second substrate processing devices, and through the second substrate processing device. The first substrate processing device is defined to perform a dry substrate processing operation. The second substrate processing device is defined to perform a wet substrate processing operation. The first substrate processing device is defined to create an energized reactive environment in exposure to a surface of the substrate in an absence of liquid material to perform the dry substrate processing operation. The second substrate processing device is defined to apply at least one material in a liquid state to the substrate to perform the wet substrate processing operation.

In another embodiment, a method is disclosed for processing a substrate. The method includes moving the substrate in a sequential manner through a plurality of substrate processing devices disposed in a separated manner within a shared ambient environment. Moving the substrate through a given substrate processing device subjects the substrate to a processing operation performed by the given substrate processing device. Some of the plurality of substrate processing devices operate to perform a dry substrate processing operation. The dry substrate processing operation does not apply any material in a liquid state to the substrate. Also, some of the plurality of substrate processing devices operate to perform a wet substrate processing operation. The wet substrate processing operation does apply at least one material in a liquid state to the substrate.

Other aspects and advantages of the invention will become more apparent from the following detailed description, taken in conjunction with the accompanying drawings, illustrating by way of example the present invention.

### BRIEF DESCRIPTION OF THE DRAWINGS

FIG. 1A shows a substrate processing system, in accordance with one embodiment of the present invention;

FIG. 1B shows a close-up side view of two sequentially disposed substrate processing devices within the system, in accordance with one embodiment of the present invention;

FIG. 1C shows a top view of a straight course version of the conveyance device relative to the plurality of substrate processing devices, in accordance with one embodiment of the present invention;

FIG. 1D shows a top view of a curved course version of the conveyance device relative to the plurality of substrate processing devices, in accordance with one embodiment of the present invention;

FIG. 1E shows a top view of a circular course version of the conveyance device relative to the plurality of substrate processing devices, in accordance with one embodiment of the present invention;

FIG. 2A shows a substrate processing system in which a wet substrate processing device is disposed to sequentially follow a dry substrate processing device relative to the movement direction of the conveyance device, in accordance with one embodiment of the present invention;

FIG. 2B shows an example of the dry substrate processing device in which a laser beam is used to create an energized reactive environment in exposure to the surface of the substrate, in an absence of liquid material, in accordance with one embodiment of the present invention;

FIG. 2C shows an example of the dry substrate processing device in which a plasma generation device is used to create an energized reactive environment, i.e., plasma, in exposure to the surface of the substrate, in an absence of liquid material, in accordance with one embodiment of the present invention;

FIG. 2D shows an example of the wet substrate processing device in which a spray bar is defined to spray a liquid processing material onto the surface of the substrate as the substrate is moved by the conveyance device, in accordance with one embodiment of the present invention;

FIG. 2E shows another example of the wet substrate processing device in which a proximity head is defined to flow a meniscus of liquid processing material onto the surface of the substrate, as the substrate is moved by the conveyance device below the proximity head, in accordance with one embodiment of the present invention;

FIG. 3 shows a flowchart of a method for processing a substrate, in accordance with one embodiment of the present invention; and

FIG. 4 shows a flowchart of a method for processing a substrate to remove photoresist material, in accordance with one embodiment of the present invention.

### DETAILED DESCRIPTION

In the following description, numerous specific details are set forth in order to provide a thorough understanding of the present invention. It will be apparent, however, to one skilled in the art that the present invention may be practiced without some or all of these specific details. In other instances, well known process operations have not been described in detail in order not to unnecessarily obscure the present invention.

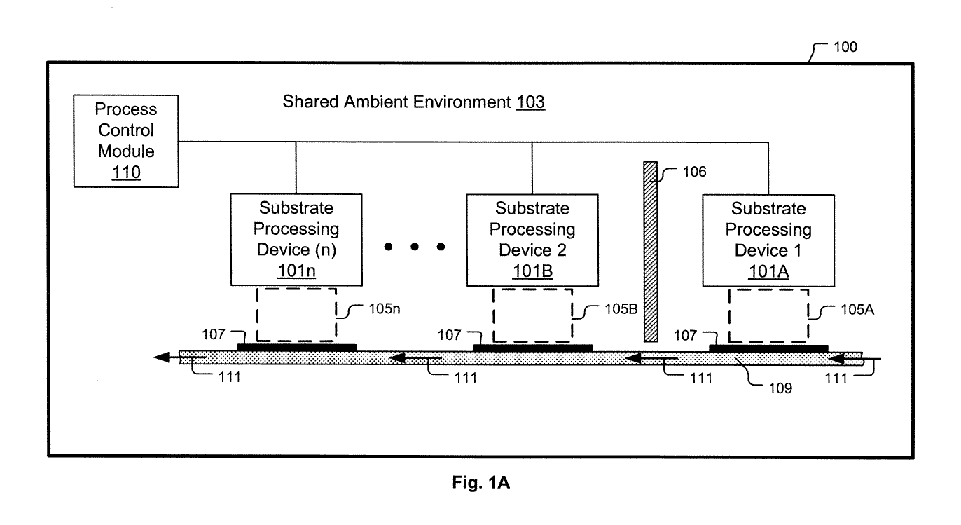

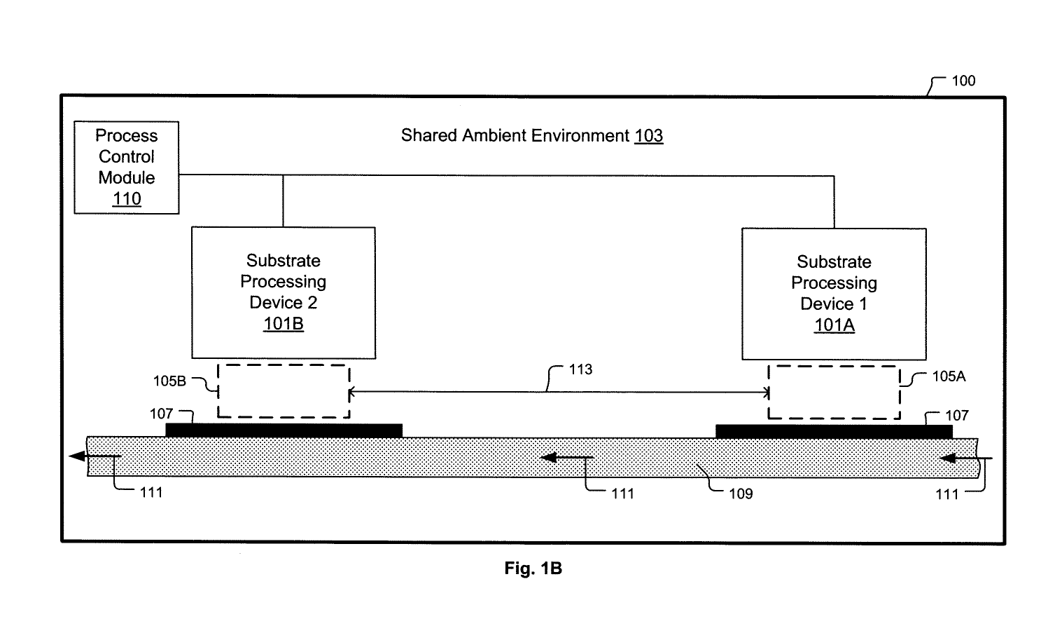

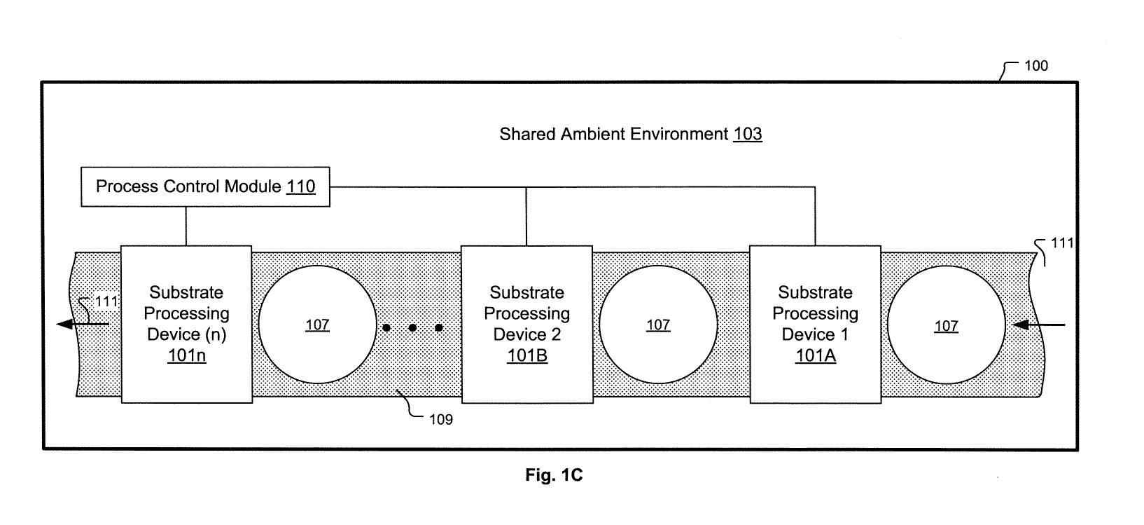

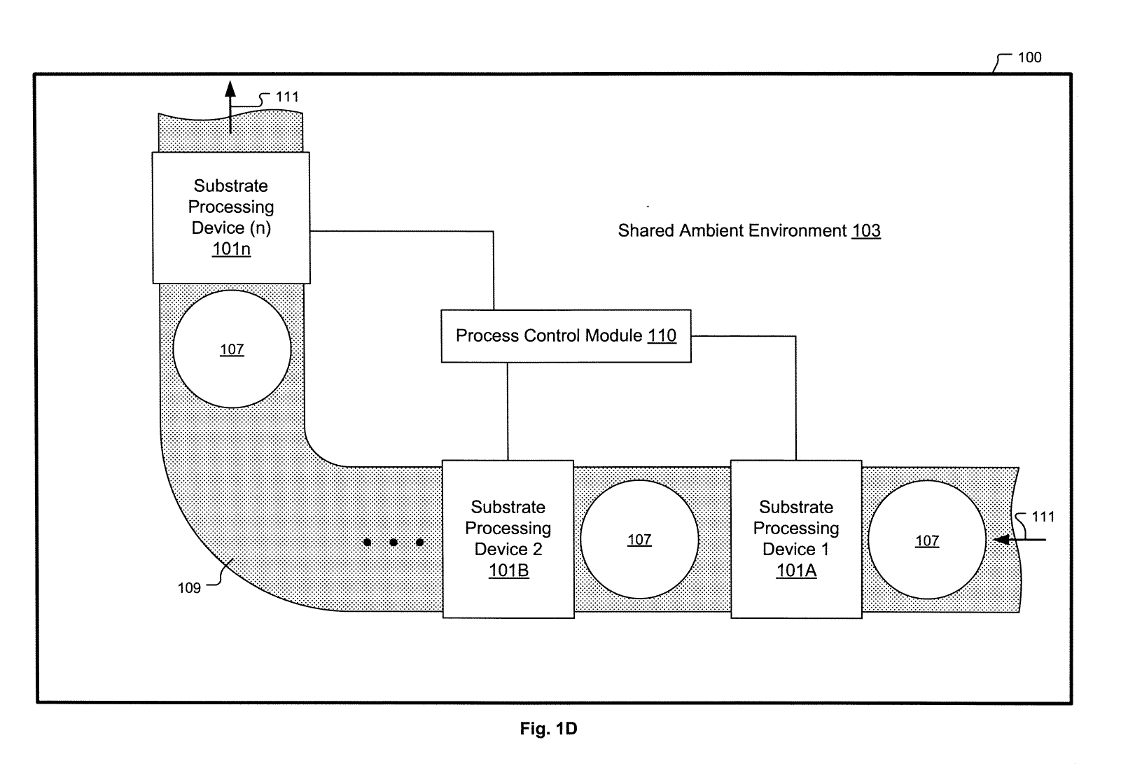

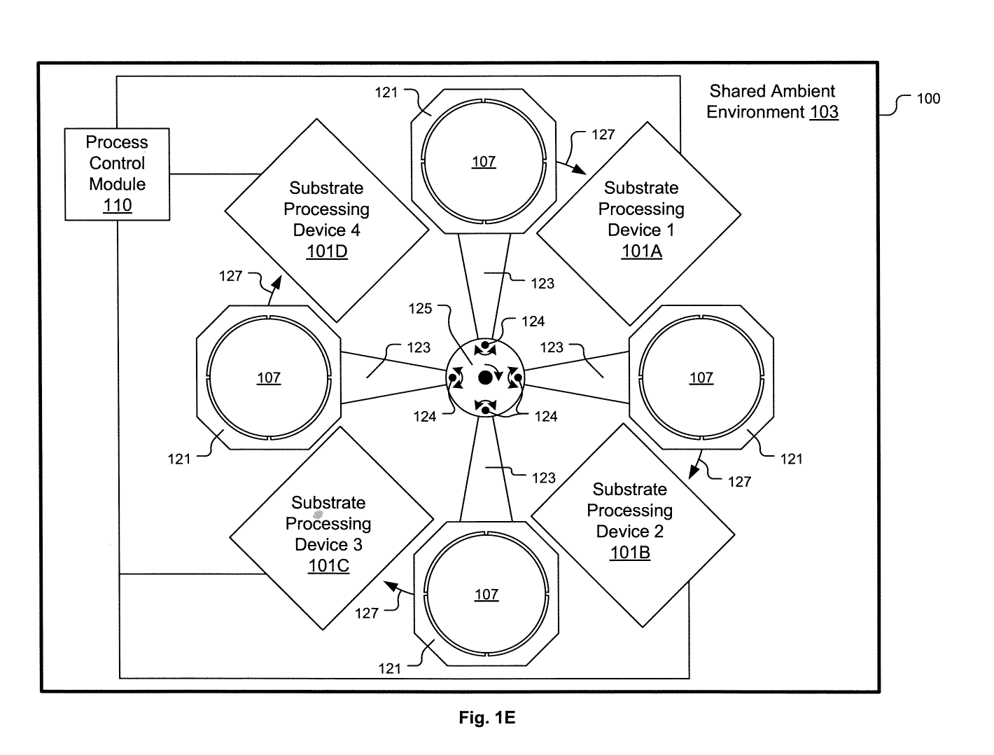

FIG. 1A shows a substrate processing system 100, in accordance with one embodiment of the present invention. The system 100 includes two or more substrate processing devices 101A-101n disposed in a separated manner within a shared ambient environment 103. For ease of discussion, any given one of the plurality of substrate processing devices 101A-101n is referred to hereafter in general terms as a substrate processing device 101. The system 100 also includes a conveyance device 109 disposed within the shared ambient environment 103. The conveyance device 109 is defined to move one or more substrates 107 through and between each of the plurality of substrate processing devices 101A-101n in a continuous manner, as indicated by arrows 111. It should be understood that the conveyance device 109 can be defined to carry either one or multiple substrates 107 through the system 100 at a given time.

In one embodiment, the conveyance device 109 is defined to move the substrate 107 through each substrate processing device 101 in a linear manner, such that a top surface of the substrate 107 is processed in a substantially uniform manner during a single pass of the substrate 107 through the substrate processing device 101. In one embodiment, the term substrate 107 as used herein refers to a semiconductor wafer. However, it should be understood that in other embodiments, the term substrate 107 as used herein can refer to substrates formed of sapphire, GaN, GaAs or SiC, or other substrate materials, and can include glass panels/substrates, metal foils, metal sheets, polymer materials, or the like. Also, in various embodiments, the substrate 107 as referred to herein may vary in form, shape, and/or size.

Each substrate processing device 101A-101n is defined to perform a process on the substrate 107 within its respective processing region 105A-105n, as the substrate 107 is moved through/past/by the substrate processing device 101A-101n. The process performed on the substrate 107 by a given substrate processing device 101 can include one or more of material modification, material removal, material deposition, and/or metrology, i.e., measurement of some characteristic of the substrate 107. Some of the substrate processing devices 101 can be defined to perform a dry substrate processing operation that does not include application of any material in a liquid state to the substrate 107. Also, some of the substrate processing devices 101 can be defined to perform a wet substrate processing operation in which at least one material in a liquid state is applied to the substrate 107.

The system 100 can include a number of shield components 106 disposed to ensure that substrate processing devices 101 that perform dry substrate processing operations are shielded with regard to liquid from the substrate processing devices 101 that perform wet substrate processing operations. In some embodiments, the shield components 106 may be physical structures, such as barriers or splash guards. In some embodiments, the shield components 106 may be non-physical barriers such as gas curtains. However, regardless of the particular embodiment, it should be understood that the shield components 106 are defined and disposed to avoid interference with movement of the substrate 107 by the conveyance device 109, and to ensure that each of the plurality of substrate processing devices 101A-101n and its respective processing region 105A-105n remains in open exposure to the shared ambient environment 103.

In one embodiment, the shared ambient environment 103 is a controlled ambient environment, having a monitored and controlled gas composition, pressure, temperature, and humidity that is suitable for substrate processing operations performed therein. The shared ambient environment 103 can also be filtered to remove particulate contaminants which may pose a threat to the substrates 107 within the system 100. The system 100 can include gas supply/removal equipment plumbed to the shared ambient environment 103. The system 100 can also include a number of pressure, temperature, and humidity monitoring and/or control devices disposed within the shared ambient environment 103, so long as these devices do not interfere with operation of the system 100 as disclosed herein. It should be appreciated that the substrate 107 is moved by the conveyance device 109 through the system 100, from one processing region 105 to another processing region 105, within the same shared ambient environment 103, without having to pass between separately controlled ambient environments, i.e., without having to move from one isolated processing chamber to a different isolated processing chamber.

In one embodiment, the system 100 includes a process control module 110 defined to control operation of one or more of the plurality of substrate processing devices 101A-101n on a substrate-by-substrate basis, as the conveyance device 109 moves substrates 107 in the continuous manner through each of the plurality of substrate processing devices 101A-101n. Although the example embodiment of FIG. 1A shows the process control module 110 disposed within the system 100, it should be understood that in other embodiments the process control module 100 can be disposed outside of the system 100, and can be connected to communicate with one or more of the substrate processing devices 101 through either a wired connection or a wireless connection. It should also be understood that in some embodiments not all substrate processing devices 101 are connected/defined to communicate with the process control module 110.

In one embodiment, at least one of the plurality of substrate processing devices 101A-101n is a scanning metrology device defined to scan the substrate 107 as the substrate 107 is moved by the conveyance device 109 through the scanning metrology device. The scanning metrology device is defined to measure and record one or more characteristics of the surface of the substrate 107 and transmit the measured characteristics to the process control module 110. In various embodiments, a scanning metrology device deployed as one of the substrate processing devices 101 within the system 100 can be defined to measure characteristics of the substrate 107 including, but not limited to, surface roughness, film thickness, contamination levels (particles, metals, ions, etc.), among others.

In one embodiment, the measured characteristics of the substrate 107 as sent to the process control module 110 serves as an input to control operation of a subsequently disposed substrate processing device 101 through which the substrate 107 will be moved by the conveyance device 109. For example, a scanning metrology device can be deployed in the system 100 to determine if a substrate 107 has been fully cleaned of a specified material. If the scanning metrology device determines that the substrate 107 is not fully clean, then the process control module 110 to which the scanning metrology device communicates can direct a subsequently disposed substrate processing device 101 to perform additional cleaning operations on the substrate 107. However, if the scanning metrology device determines that the substrate 107 is fully clean, then the process control module 110 to which the scanning metrology device communicates can direct a subsequently disposed substrate processing device 101 to not perform additional cleaning operations on the substrate 107, which may avoid adverse affects from over-cleaning of the substrate 107.

FIG. 1B shows a close-up side view of two sequentially disposed substrate processing devices 101A and 101B within the system 100, in accordance with one embodiment of the present invention. Each of the substrate processing devices 101A and 101B includes a respective processing region 105A and 10B to which the substrate 107 is exposed as it is moved by the conveyance device 109. There may be a time consideration with regard to moving the substrate 107 from one substrate processing device, e.g., 101A, to a sequentially disposed substrate processing device, e.g., 101B. A separation distance 113 between the two sequentially disposed substrate processing devices 101A and 101B, and a rate of travel of the conveyance device 109 between the two sequentially disposed substrate processing devices 101A and 101B, are defined to ensure that a condition imparted to the substrate 107 by the first substrate processing device 101A is sustained until processing of the substrate 107 by the second 101B substrate processing device.

For example, the substrate processing device 101A can perform a process within the region 105A that temporarily modifies a layer of material on the substrate, such that the modified layer of material can be removed by a subsequent process. It is necessary for the substrate 107 to be subjected to the subsequent process before the temporarily modified layer of material returns to its unmodified state. In this example, the separation distance 113 and velocity of the conveyance device 109 are defined to ensure that the substrate 107 is moved through the processing region 105B of the next substrate processing device 101B before the temporarily modified layer of material returns to its unmodified state.

The above-described example may occur in many instances during substrate processing. For instance, if an oxidization layer of a material prone to rapid oxidization needs to be removed to enable processing of the bare material, then the first substrate processing device 105A can function to remove the oxidation layer, with the substrate 107 being conveyed through the second processing region 105B of the second substrate processing device 101B before the oxidization layer can reform. In another example, the substrate 107 may have disposed thereon a bulk photoresist material covered by an insoluble cross-linked photoresist crust material. In this example, the first substrate processing device 101A can function to temporarily modify the cross-linked photoresist crust material so that it is soluble in a wet processing operation, then the second substrate processing device 101B can perform a wet substrate processing operation to remove, e.g., dissolve, both the modified cross-linked photoresist material and the underlying bulk photoresist material.

In conventional substrate processing, the substrate would normally have to be transferred from one isolated chamber to another isolated chamber for sequential processing operations that were not compatible for performance in a single chamber, i.e., dry processing quickly followed by wet processing. This transfer of the substrate from chamber-to-chamber typically involves traversal through environmental isolation equipment, and can result in substantial time delay relative to process time scales. Therefore, the chamber-to-chamber processing paradigm is limited in regard to the diversity of processes that can be performed in a sufficiently rapid sequential manner. It should be appreciated that chamber-to-chamber transfer of the substrate 107 is not required in the system 100 in order to perform diverse processing operations in a rapidly sequential manner. More specifically, in the system 100 the substrate 107 is moved and processed in a continuous manner within a shared ambient environment 103.

In one embodiment, the conveyance device 109 is defined to include multiple substrate holding regions formed in a spaced apart manner to carry multiple substrates 107 through the system 100 at a given time. However, in another embodiment, the conveyance device 109 is defined to include a single substrate holding region to carry a single substrate through the system 100 at a given time. In one embodiment, the conveyance device 109 is defined as a conveyor belt having one or more substrate holding regions formed therein. In another embodiment, the conveyance device 109 includes a number of independently movable substrate supports that each include one or more substrate holding regions. In this embodiment, the independently movable substrate supports are connected to a motion control device that maintains appropriate orientation, position, and motion of the substrate support as it moves through the system 100. It should be understood, however, that regardless of the specific embodiment of the conveyance device 109, the conveyance device 109 is defined to move in a continuous manner through the system 100 in exposure to the shared ambient environment 103, such that each substrate carried by the conveyance device 109 is exposed to processing by the plurality of substrate processing devices 101 disposed within the system 100.

Also, it should be understood that in some embodiments, the substrate holding regions of the conveyance device 109 are defined to hold the substrate such that a bottom side of the substrate is substantially uncontacted by the conveyance device 109. In one example, substantially uncontacted means that the bottom side of the substrate may be contacted at a few peripheral location to provide support for the substrate, while leaving a majority of the bottom side of the substrate uncontacted. The amount and locations of support contact with the bottom side of substrate can vary between different embodiments. Some example embodiments of substrate support configurations that may be utilized in the substrate holding regions of the conveyance device 109 are described in co-pending U.S. patent application Ser. No. 11/537,501, filed Sep. 29, 2006, entitled “CARRIER FOR REDUCING ENTRANCE AND/OR EXIT MARKS LEFT BY A SUBSTRATE-PROCESSING MENISCUS,” which is incorporated in its entirety herein by reference.

FIG. 1C shows a top view of a straight course version of the conveyance device 109 relative to the plurality of substrate processing devices 101A-101n, in accordance with one embodiment of the present invention. In this embodiment, each substrate 107 is moved by the conveyance device 109 in a linear manner, i.e., straight-line manner, through the system 100 to be exposed to processing by the plurality of substrate processing devices 101.

FIG. 1D shows a top view of a curved course version of the conveyance device 109 relative to the plurality of substrate processing devices 101A-101n, in accordance with one embodiment of the present invention. In this embodiment, each substrate 107 is moved by the conveyance device 109 in an arbitrary path, i.e., including curves/turns, through the system 100. In one version of this embodiment, the conveyance device 109 is defined to move each substrate 107 through each substrate processing device 101 in a substantially linear manner, such that curves/turns made by the conveyance device exist in regions between substrate processing device 101 locations. Regardless of the particular embodiment, it should be understood that the conveyance device 109 is defined to hold the substrate 107 in an appropriate orientation and distance from each substrate processing device 101, as the substrate is moved through/past/by the substrate processing device 101 and is subjected to corresponding substrate processing operations. In one embodiment, the conveyance device 109 is defined to move each substrate 107 along a semi-circular path that enables loading and unloading of each substrate 107 onto/from the conveyance device 109 in a compact space.

FIG. 1E shows a top view of a circular course version of the conveyance device 109 relative to the plurality of substrate processing devices 101A-101n, in accordance with one embodiment of the present invention. In this example embodiment, the conveyance device 109 includes a number of substrate supports 121 connected by a respective arm member 123 to a central rotatable hub member 125. Each substrate support 121 is defined to hold a substrate 107 and move the substrate 107 through the plurality of substrate processing devices 101A-101D, as shown by arrows 127.

In one embodiment, each arm member 123 can be rotated in a controlled manner about a respective pin 124 connected to the central rotatable hub member 125, such that a velocity of each substrate support 121 relative to a given substrate processing device 101 can be independently controlled within a given velocity range, as the central hub member 125 rotates. Also, in this embodiment, each arm member 123 can be defined to extend and retract in a telescoping manner to enable proper positioning of the corresponding substrate support 121 relative to a given substrate processing device 101, as the arm member 123 is rotated about its pin 124 while the central hub member 125 rotates. The example configuration of FIG. 1E shows four substrate supports 121 and four substrate processing devices 101. However, it should be understood that the number of substrate supports 121 and the number of substrate processing devices 101 can vary in different embodiments.

It should also be understood that the straight, curved, and circular course versions of the conveyance device 109 as depicted in FIGS. 1C-1E represent examples of how the conveyance device 109 and the plurality of substrate processing devices 101A-101n may be defined within the shared ambient environment 103. In other embodiments, the conveyance device 109 and the plurality of substrate processing devices 101A-101n may be defined as a combination of the example configurations depicted in FIGS. 1C-1E, or in essentially any configuration different from those depicted in the examples of FIGS. 1C-1E, so long as the conveyance device 109 is defined to move the substrate 107 in a continuous manner through and between the plurality of substrate processing devices 101A-101n, with both the conveyance device 109 and the plurality of substrate processing devices 101A-101n disposed within the shared ambient environment 103.

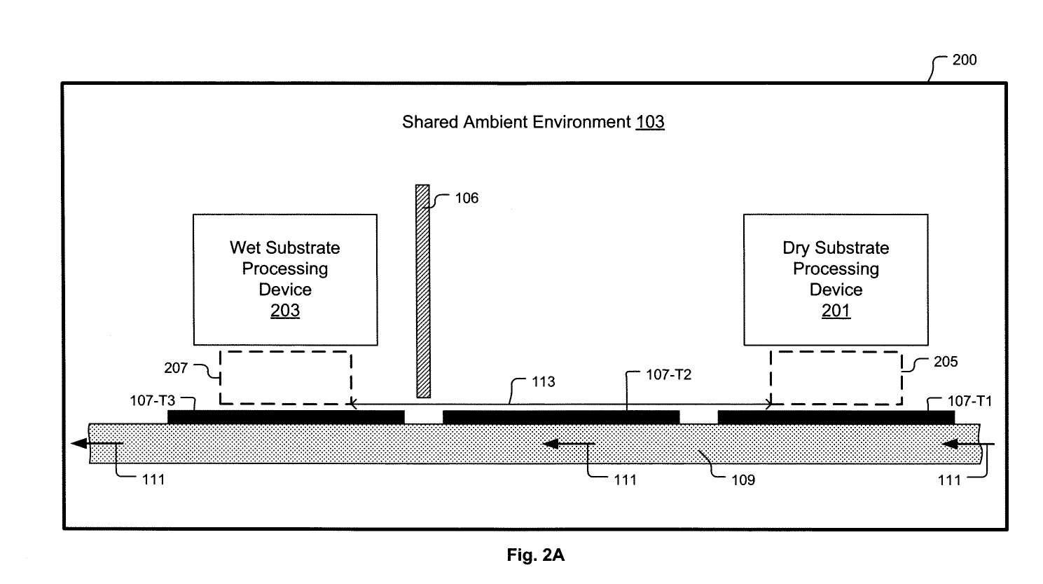

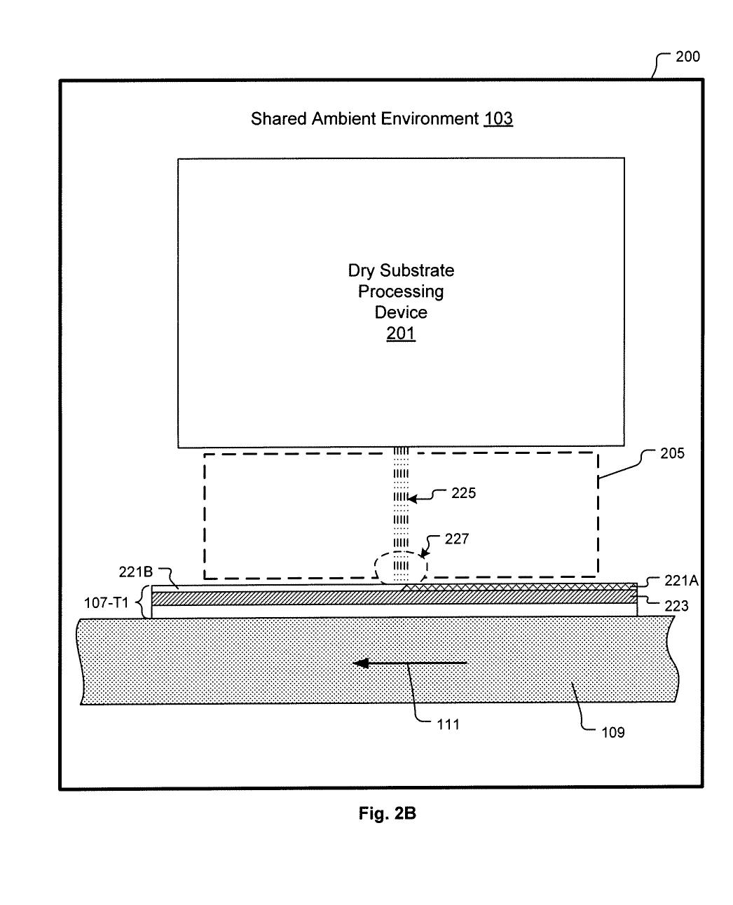

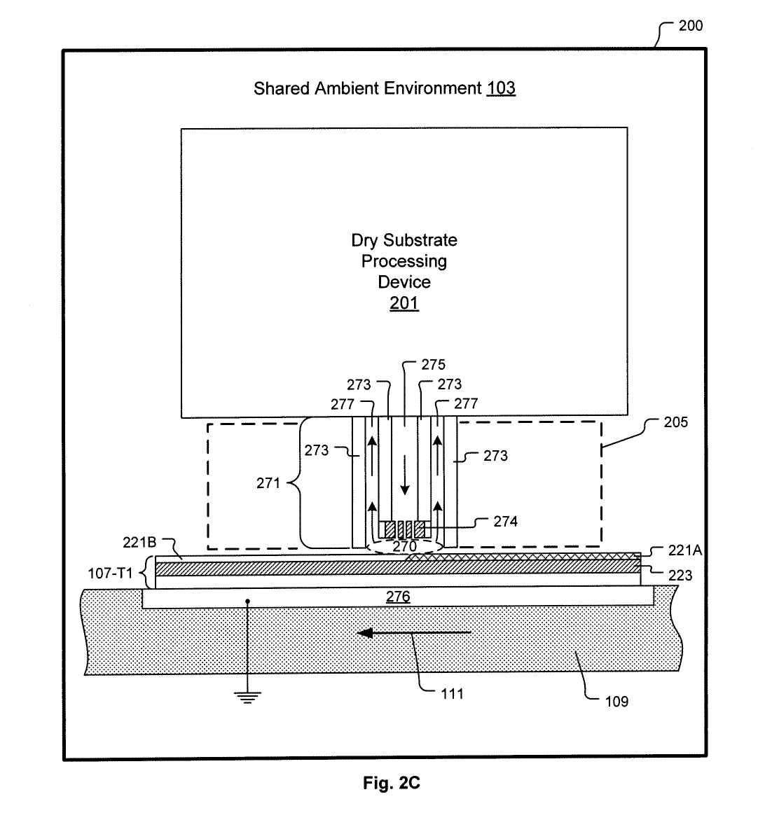

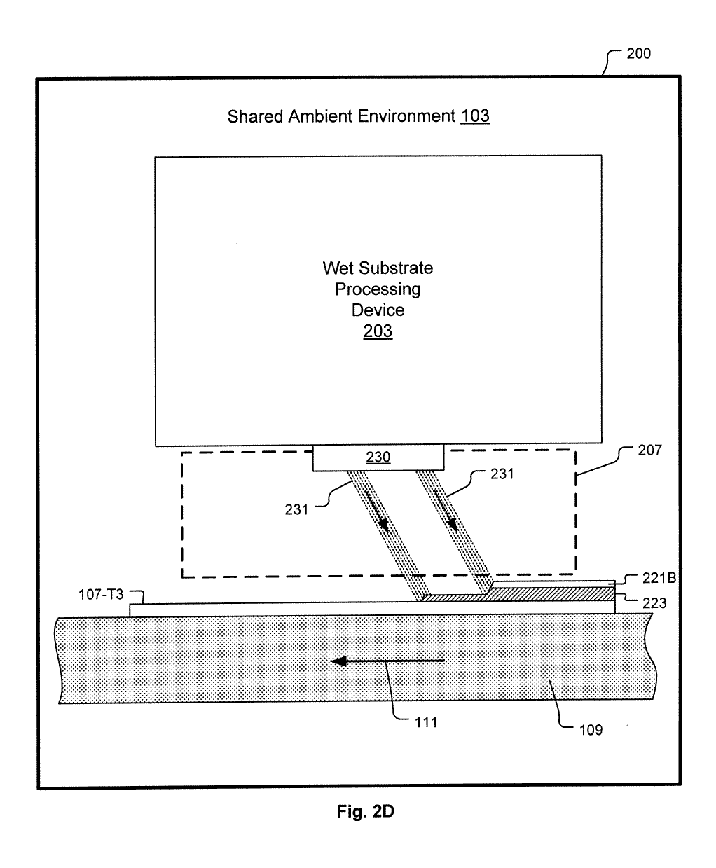

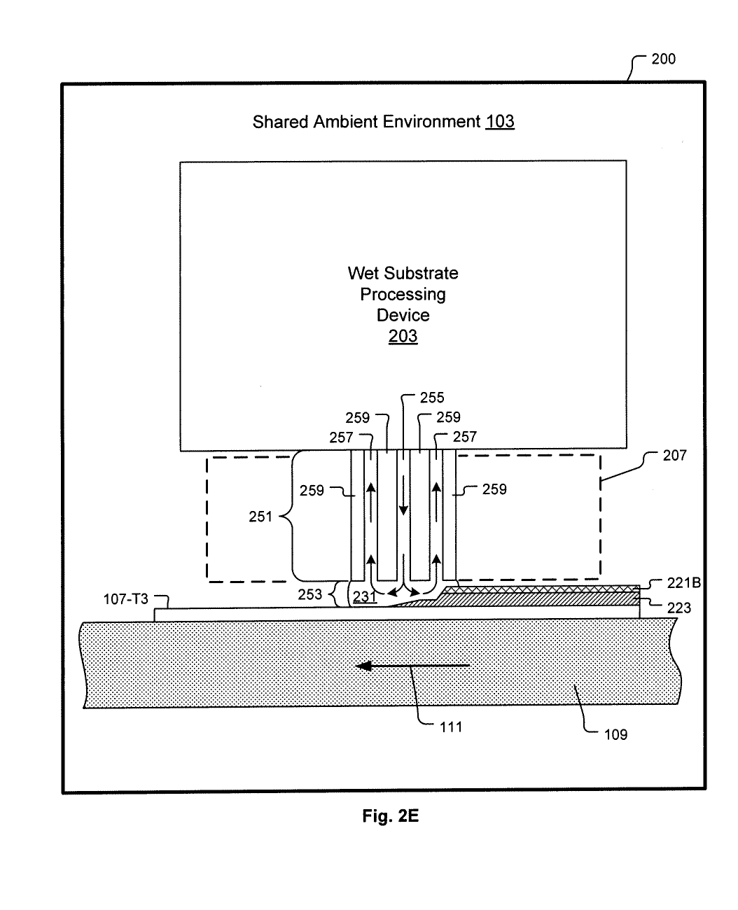

FIG. 2A shows a substrate processing system 200 in which a wet substrate processing device 203 is disposed to sequentially follow a dry substrate processing device 201 relative to the movement direction 111 of the conveyance device 109, in accordance with one embodiment of the present invention. In this embodiment, the dry substrate processing device 201 is defined to perform dry substrate processing operations on the substrate 107 within a processing region 205 as the substrate 107 is moved through/past/by/below the dry substrate processing device 201. In one embodiment, the dry substrate processing device 201 is defined to create an energized reactive environment in exposure to a surface of the substrate 107, in an absence of liquid material, to perform the dry substrate processing operation. In one version of this embodiment, the energized reactive environment is created to modify and/or remove one or more materials present on the surface of the substrate 107.

The wet substrate processing device 203 is defined to perform wet substrate processing operations on the substrate 107 within a processing region 207 as the substrate 107 is moved through/past/by/below the wet substrate processing device 203. The wet substrate processing device 203 is defined to apply at least one material in a liquid state to the substrate 107 to perform the wet substrate processing operation.

In one embodiment, the dry substrate processing device 201 is shielded with regard to liquid that may emanate from the wet substrate processing device 203 by one or more shield components 106, as discussed above with regard to FIG. 1A. Movement of the substrate 107 through the system 200 by the conveyance device 109 is depicted by the substrate 107-T1 passing through the dry substrate processing device 201 at a first time T1, then by the substrate 107-T2 passing between the dry and wet substrate processing devices (201 and 203) at a second time T2, then by the substrate 107-T3 passing through the wet substrate processing device 203 at a third time T3.

The dry-wet configuration of the system 200 is well-suited to perform many processes that require rapid sequential dry and wet processing of the substrate 107. One such process involves the removal, i.e., cleaning, of photoresist material from the substrate 107, where the photoresist material is defined by a bulk photoresist material disposed on the top surface of the substrate 107, with a cross-linked photoresist crust material disposed over the bulk photoresist material. In this photoresist removal process, the cross-linked photoresist crust material is difficult to remove with wet substrate processing alone. However, the cross-linked photoresist crust material can be modified in a dry substrate processing operation to become removable by a subsequent wet substrate processing operation. Therefore, the dry substrate processing device 201 can be operated to modify the cross-linked photoresist crust material to render it removable in a subsequent wet substrate processing operation. Then, the wet substrate processing device 203 can be operated to remove both the modified cross-linked photoresist crust material and the bulk photoresist crust material through wet substrate processing.

FIG. 2B shows an example of the dry substrate processing device 201 in which a laser beam 225 is used to create an energized reactive environment 227 in exposure to the surface of the substrate 107-T1, in an absence of liquid material, in accordance with one embodiment of the present invention. The substrate 107-T1 is shown to have a bulk photoresist material 223 disposed thereon, and a cross-linked photoresist crust material 221A disposed over the bulk photoresist material 223. The energized reactive environment 227 is created to modify and/or remove one or more materials present on the surface of the substrate 107-T1. In the embodiment of FIG. 2B, the energized reactive environment 227 is created by the laser beam 225 to modify the cross-linked photoresist crust material 221A into a modified cross-linked photoresist material 221B that is capable of being removed by a subsequent wet substrate processing operation in the wet substrate processing device 203.

In one embodiment, in addition to utilizing the laser beam 225 to create the energized reactive environment 227 on the surface of the substrate 107-T1, one or more gases can be flowed to the substrate to enable or enhance creation of the energized reactive environment 227. The one or more gases in this embodiment may include reactive neutrals and/or ions that modify the cross-linked photoresist crust material 221A in such a way as to enable a complete removal of both the modified cross-linked photoresist material 221B and bulk photoresist material 223 in the subsequent wet processing operation. Also, in one embodiment, the laser beam 225 generation device is defined to scan the laser beam 225 of energy across the surface of the substrate 107-T1 in a rasterized manner, i.e., side-to-side manner, as the substrate 107-T1 is moved by the conveyance device 109, such that an entirety of the substrate 107-T1 surface is exposed to the laser beam 225.

FIG. 2C shows an example of the dry substrate processing device 201 in which a plasma generation device 271 is used to create an energized reactive environment 270, i.e., plasma 270, in exposure to the surface of the substrate 107-T1, in an absence of liquid material, in accordance with one embodiment of the present invention. Again, the energized reactive environment 270 is created to modify and/or remove one or more materials present on the surface of the substrate 107-T1. In the embodiment of FIG. 2C, the plasma 270 is created to modify the cross-linked photoresist crust material 221A into a modified cross-linked photoresist material 221B that is capable of being removed by a subsequent wet substrate processing operation in the wet substrate processing device 203.

The plasma generation device 271 includes a gas supply channel 275 and outer gas return channels 277. The gas supply channel 275 is separated from the outer gas return channels 277 by walls 273. And, the outer gas return channels 277 are defined by outer walls 273. The plasma generation device 271 also includes an electrode 274 disposed to be near to the substrate 107 as the substrate 107 moves below the plasma generation device 271. In the embodiment of FIG. 2C, the electrode 274 includes a number of gas flow passages through which reactant gas is flowed from the gas supply channel 275 to reach the surface of the substrate 107-T1. Also, in the embodiment of FIG. 2C, the conveyance device 109 includes a grounded electrode 276 positioned below the substrate 107-T1.

During operation, reactant gas is flowed through the gas supply channel 275 and electrode 274 to the substrate 107-T1, and radiofrequency (RF) power is applied to the electrode 274 to transform the reactant gas into the plasma 270 in exposure to the surface of the substrate 107-T1. The reactant gas is exhausted from the plasma 270 region through the outer gas return channels 277. The plasma 270 is defined to either remove or modify the cross-linked photoresist crust material 221A such that it can be removed in a subsequent wet processing operation.

In one embodiment, the plasma generation device 271 is defined such that the plasma 270 generation region covers a diameter of the substrate 107-T1, thereby allowing an entirety of the top surface of the substrate 107-T1 to be exposed to the plasma 270 in a single pass of the substrate 107-T1 through the dry substrate processing device 201. In another embodiment, the plasma generation device 271 is defined to generate a local plasma 270 in exposure to the surface of the substrate 107-T1, and scan the local plasma 270 across the surface of the substrate 107-T1 in a rasterized manner as the substrate 107-T1 is moved by the conveyance device 109. It should be understood that the configuration of the plasma generation device 271 in FIG. 2C is provided by way of example. In other embodiments, the plasma generation device 271 can have a different configuration and/or operation means, so long as the plasma generation device 271 is defined to create the plasma 270 in exposure to the substrate 107-T1.

FIG. 2D shows an example of the wet substrate processing device 203 in which a spray bar 230 is defined to spray a liquid processing material 231 onto the surface of the substrate 107-T3 as the substrate is moved by the conveyance device 109, in accordance with one embodiment of the present invention. In one embodiment, one or more megasonic transducers can be deployed within the spray bar 230 to impart megasonic energy to the liquid material 231 as it is sprayed onto the substrate 107-T3. The liquid material 231 is formulated to remove both the modified cross-linked photoresist material 221B and the underlying bulk photoresist material 223. In one embodiment, a single spray pattern of liquid material 231 can be directed toward the substrate 107-T3. In other embodiments, such as that shown in FIG. 2D, multiple spray patterns of liquid material 213 can be directed toward the substrate 107-T3.

FIG. 2E shows another example of the wet substrate processing device 203 in which a proximity head 251 is defined to flow a meniscus 253 of liquid processing material 231 onto the surface of the substrate 107-T3, as the substrate 107-T3 is moved by the conveyance device 109 below the proximity head 251, in accordance with one embodiment of the present invention. The meniscus 253 is formed between the substrate 107-T3 and the proximity head 251. In one embodiment, the proximity head 251 is defined such that the meniscus 253 of liquid processing material 231 covers a diameter of the substrate 107-T3, thereby allowing an entirety of the top surface of the substrate 107-T3 to be exposed to the meniscus 253 in a single pass of the substrate 107-T3 through the wet substrate processing device 203.

The proximity head 251 includes a fluid supply channel 255 and outer fluid return channels 257. The fluid supply channel 255 is separated from the outer fluid return channels 257 by walls 259. And, the outer fluid return channels 257 are defined by outer walls 259. During operation, the liquid processing material 231 is flowed through the fluid supply channel 255 to the substrate 107-T3, and back through the outer fluid return channels 257, thereby forming the meniscus 253 of liquid processing material 231 on the substrate 107-T3. The liquid processing material 231 is formulated to remove both the modified cross-linked photoresist material 221B and the underlying bulk photoresist material 223. It should be understood that the configuration of the proximity head 251 in FIG. 2C is provided by way of example. In other embodiments, the proximity head 251 can have a different configuration and/or operation means, so long as the meniscus 253 of liquid processing material 231 is formed in exposure to the substrate 107-T3.

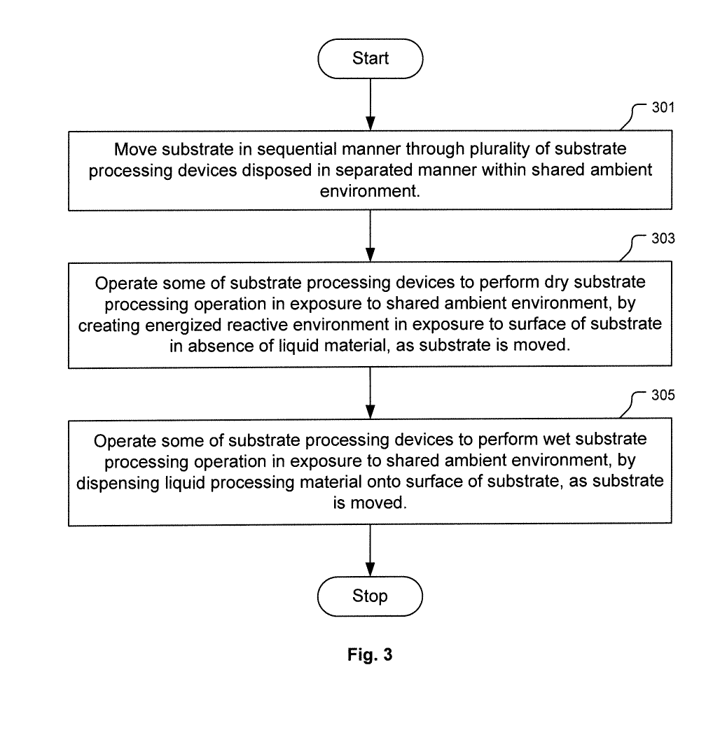

FIG. 3 shows a flowchart of a method for processing a substrate, in accordance with one embodiment of the present invention. The method includes an operation 301 in which a substrate is moved in a sequential manner through a plurality of substrate processing devices that are disposed in a separated manner within a shared ambient environment. Moving the substrate through a given substrate processing device subjects the substrate to a processing operation performed by the given substrate processing device. The method can include operating a conveyance device disposed within the shared ambient environment to move the substrate through and between each of the plurality of substrate processing devices in a continuous manner.

Some of the plurality of substrate processing devices operate to perform dry substrate processing operations. And, some of the plurality of substrate processing devices operate to perform wet substrate processing operations. The method also includes an operation 303 in which some of the substrate processing devices are operated to perform one or more dry substrate processing operations on the substrate in exposure to the shared ambient environment. Any given dry substrate processing operation does not apply any material in a liquid state to the substrate. The method further includes an operation 305 in which some of the substrate processing devices are operated to perform one or more wet substrate processing operations on the substrate in exposure to the shared ambient environment. The one or more wet substrate processing operations do apply at least one material in a liquid state to the substrate, as the substrate is moved.

The one or more dry substrate processing operations are performed by creating an energized reactive environment in exposure to the surface of the substrate in an absence of liquid material, as the substrate is moved. The energized reactive environment is created to modify and/or remove one or more materials present on the surface of the substrate. In one embodiment, such as that described with regard to FIG. 2B, creating the energized reactive environment includes operating a laser generation device to direct a laser beam of energy toward the surface of the substrate. In another embodiment, such as that described with regard to FIG. 3C, creating the energized reactive environment includes operating a plasma generation device to generate a plasma in exposure to the surface of the substrate.

The one or more wet substrate processing operations are performed by applying processing material in a liquid font to the substrate as the substrate is moved. In one embodiment, such as that described with regard to FIG. 2D, some of the plurality of substrate processing devices are operated to perform a wet substrate processing operation by spraying liquid processing material onto the surface of the substrate as the substrate is moved. In another embodiment, such as that described with regard to FIG. 2E, some of the plurality of substrate processing devices are operated to perform a wet substrate processing operation by flowing a meniscus of liquid processing material onto the surface of the substrate between the substrate and a proximity head as the substrate is moved below the proximity head.

The method can also include an operation for controlling a movement time of the substrate between two sequentially disposed substrate processing devices to ensure that a condition imparted to the substrate by a first of the two sequentially disposed substrate processing devices is sustained until processing of the substrate by a second of the two sequentially disposed substrate processing devices. In this embodiment, controlling the movement time of the substrate between the two sequentially disposed substrate processing devices includes controlling a separation distance between the two sequentially disposed substrate processing devices, a rate of travel of the substrate between the two sequentially disposed substrate processing devices, or a combination thereof.

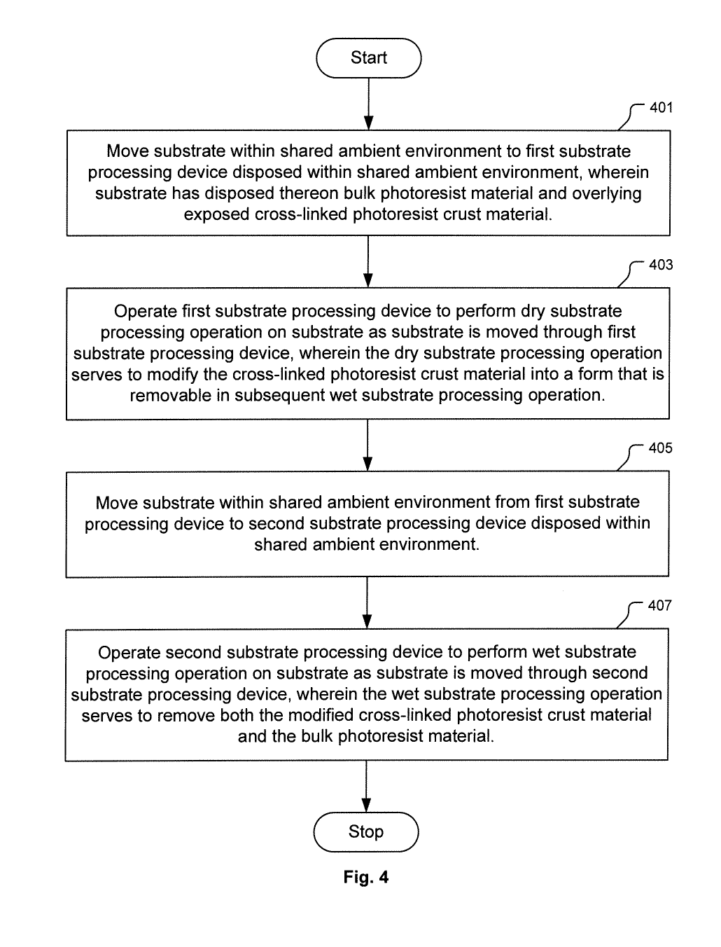

FIG. 4 shows a flowchart of a method for processing a substrate to remove photoresist material, in accordance with one embodiment of the present invention. The method includes an operation 401 for moving the substrate within a shared ambient environment to a first substrate processing device disposed within the shared ambient environment. The substrate has disposed thereon a bulk photoresist material, and a cross-linked photoresist material overlying the bulk photoresist material. The method also includes an operation 403 for operating the first substrate processing device to perform a dry substrate processing operation on the substrate as the substrate is moved through the first substrate processing device. The dry substrate processing operation serves to modify the cross-linked photoresist crust material into a form that is removable in a subsequent wet substrate processing operation.

The method continues with an operation 405 to move the substrate within the shared ambient environment from the first substrate processing device to a second substrate processing device also disposed within the shared ambient environment. The method then proceed with an operation 407 in which the second substrate processing device is operated to perform a wet substrate processing operation on the substrate as the substrate is moved through the second substrate processing device. The wet substrate processing operation serves to remove both the modified cross-linked photoresist crust material and the underlying bulk photoresist material.

As disclosed herein, the multiple processing region, sequential processing system can be utilized to remove, deposit, and/or modify essentially any layered combination of materials from/to any type of substrate in a shared, i.e., common, ambient environment. This is particularly useful where the different layered materials require different types of processing that can be implemented within respective processing regions of the sequential processing system. In the sequential processing system, the multiple substrate processing devices can be positioned in essentially any manner necessary to achieve desired substrate processing results. Also, because the substrate is moved within the shared ambient environment, and because the substrate processing devices are also deployed within the shared ambient environment, sequential processing operations can be performed on a substrate with small intervening time delay.

While this invention has been described in terms of several embodiments, it will be appreciated that those skilled in the art upon reading the preceding specifications and studying the drawings will realize various alterations, additions, permutations and equivalents thereof. It is therefore intended that the present invention includes all such alterations, additions, permutations, and equivalents as fall within the true spirit and scope of the invention.

What is claimed is:

1. A substrate processing system, comprising:
a plurality of substrate processing devices disposed in a separated manner within a shared ambient environment; and
a conveyance device disposed within the shared ambient environment and defined to move a substrate through and between each of the plurality of substrate processing devices in a continuous manner.

2. The substrate processing system of claim 1, wherein a separation distance between two sequentially disposed substrate processing devices and a rate of travel of the conveyance device between the two sequentially disposed substrate processing devices are defined to ensure that a condition imparted to a substrate by a first of the two sequentially disposed substrate processing devices is sustained until processing of the substrate by a second of the two sequentially disposed substrate processing devices.

3. The substrate processing system of claim 1, wherein some of the plurality of substrate processing devices are defined to perform a dry substrate processing operation, and wherein some of the plurality of substrate processing devices are defined to perform a wet substrate processing operation, wherein the dry substrate processing operation does not apply any material in a liquid state to the substrate, and wherein the wet substrate processing operation does apply at least one material in a liquid state to the substrate.

4. The substrate processing system of claim 3, wherein at least one of the substrate processing devices that is defined to perform dry substrate processing operations is defined to create an energized reactive environment in exposure to a surface of the substrate in an absence of liquid material, wherein the energized reactive environment is created to modify or remove one or more materials present on the surface of the substrate.

5. The substrate processing system of claim 4, wherein at least one of the substrate processing devices that is defined to create the energized reactive environment includes a laser generation device defined to direct a laser beam of energy toward the surface of the substrate.

6. The substrate processing system of claim 4, wherein at least one of the substrate processing devices that is defined to create the energized reactive environment includes a plasma generation device defined to generate a plasma in exposure to the surface of the substrate.

7. The substrate processing system of claim 3, wherein at least one of the substrate processing devices that is defined to perform wet substrate processing operations includes a spray bar defined to spray a liquid processing material onto the surface of the substrate as the substrate is moved by the conveyance device.

8. The substrate processing system of claim 3, wherein at least one of the substrate processing devices that is defined to perform wet substrate processing operations includes a proximity head defined to flow a meniscus of liquid processing material onto the surface of the substrate between the substrate and the proximity head as the substrate is moved by the conveyance device below the proximity head.

9. The substrate processing system of claim 1, further comprising:
a process control module defined to control operation of one or more of the plurality of substrate processing devices on a substrate-by-substrate basis as the conveyance device moves substrates through each of the plurality of substrate processing devices in the continuous manner.

10. The substrate processing system of claim 9, wherein at least one of the plurality of substrate processing devices is a scanning metrology device defined to scan the substrate as the substrate is moved by the conveyance device through the scanning metrology device, wherein the scanning metrology device is defined to measure and record one or more characteristics of the surface of the substrate and transmit the measured characteristics to the process control module to serve as an input to control operation of a subsequently disposed substrate processing device through which the substrate will be moved by the conveyance device.

11. The substrate processing system of claim 1, wherein the conveyance device is defined to include multiple substrate holding regions formed in a spaced apart manner.

12. A substrate processing system, comprising:
a first substrate processing device disposed within a shared ambient environment;
a second substrate processing device disposed within the shared ambient environment and separate from the first substrate processing device;
a conveyance device disposed within the shared ambient environment and defined to move a substrate in a continuous manner through the first substrate processing device, between the first and second substrate processing devices, and through the second substrate processing device,
wherein the first substrate processing device is defined to perform a dry substrate processing operation, and wherein the second substrate processing device is defined to perform a wet substrate processing operation, wherein the first substrate processing device is defined to create an energized reactive environment in exposure to a surface of the substrate in an absence of liquid material to perform the dry substrate processing operation, and wherein the second substrate processing device is defined to apply at least one material in a liquid state to the substrate to perform the wet substrate processing operation.

13. The substrate processing system as recited in claim 12, wherein the energized reactive environment is created to modify or remove one or more materials present on the surface of the substrate.

14. The substrate processing system as recited in claim 13, wherein the first substrate processing device includes a laser generation device defined to direct a laser beam of energy toward the surface of the substrate and scan the laser beam of energy across the surface of the substrate in a rasterized manner as the substrate is moved by the conveyance device.

15. The substrate processing system as recited in claim 13, wherein the first substrate processing device includes a plasma generation device defined to generate a local plasma in exposure to the surface of the substrate as the substrate is moved by the conveyance device.

16. The substrate processing system as recited in claim 12, wherein the first substrate processing device is shielded with regard to liquid from the second substrate processing device.

17. The substrate processing system as recited in claim 12, wherein the second substrate processing device includes a spray bar defined to spray a liquid processing material onto the surface of the substrate as the substrate is moved by the conveyance device.

18. The substrate processing system as recited in claim 12, wherein the second substrate processing device includes a proximity head defined to flow a meniscus of liquid processing material onto the surface of the substrate between the substrate and the proximity head as the substrate is moved by the conveyance device below the proximity head.

19. The substrate processing system as recited in claim 12, wherein a separation distance between the first and second substrate processing devices and a rate of travel of the conveyance device between the first and second substrate processing devices are defined to ensure that a condition imparted to a substrate by the first substrate processing device is sustained until processing of the substrate by the second substrate processing device.

20. The substrate processing system as recited in claim 12, wherein the conveyance device is defined to include multiple substrate holding regions formed in a spaced apart manner.

21. A method for processing a substrate, comprising:
moving the substrate in a sequential manner through a plurality of substrate processing devices disposed in a separated manner within a shared ambient environment,
wherein moving the substrate through a given substrate processing device subjects the substrate to a processing operation performed by the given substrate processing device, and
wherein some of the plurality of substrate processing devices operate to perform a dry substrate processing operation, and wherein some of the plurality of substrate processing devices operate to perform a wet substrate processing operation, wherein the dry substrate processing operation does not apply any material in a liquid state to the substrate, and wherein the wet substrate processing operation does apply at least one material in a liquid state to the substrate.

22. The method for processing a substrate as recited in claim 21, further comprising:
operating a conveyance device disposed within the shared ambient environment to move the substrate through and between each of the plurality of substrate processing devices in a continuous manner.

23. The method for processing a substrate as recited in claim 21, further comprising:
controlling a movement time of the substrate between two sequentially disposed substrate processing devices to ensure that a condition imparted to the substrate by a first of the two sequentially disposed substrate processing devices is sustained until processing of the substrate by a second of the two sequentially disposed substrate processing devices.

24. The method for processing a substrate as recited in claim 23, wherein controlling the movement time of the substrate between two sequentially disposed substrate processing devices includes controlling a separation distance between the two sequentially disposed substrate processing devices, a rate of travel of the substrate between the two sequentially disposed substrate processing devices, or a combination thereof.

25. The method for processing a substrate as recited in claim 21, further comprising:
operating some of the plurality of substrate processing devices to perform a dry substrate processing operation by creating an energized reactive environment in exposure to a surface of the substrate in an absence of liquid material as the substrate is moved, wherein the energized reactive environment is created to modify or remove one or more materials present on the surface of the substrate.

26. The method for processing a substrate as recited in claim 25, wherein creating the energized reactive environment includes operating a laser generation device to direct a laser beam of energy toward the surface of the substrate.

27. The method for processing a substrate as recited in claim 25, wherein creating the energized reactive environment includes operating a plasma generation device to generate a plasma in exposure to the surface of the substrate.

28. The method for processing a substrate as recited in claim 21, further comprising:
operating some of the plurality of substrate processing devices to perform a wet substrate processing operation by spraying liquid processing material onto the surface of the substrate as the substrate is moved.

29. The method for processing a substrate as recited in claim 21, further comprising:
operating some of the plurality of substrate processing devices to perform a wet substrate processing operation by flowing a meniscus of liquid processing material onto the surface of the substrate between the substrate and a proximity head as the substrate is moved below the proximity head.

30. The method for processing a substrate as recited in claim 21, wherein the plurality of substrate processing devices includes a first substrate processing device defined to perform a dry substrate processing operation and a second substrate processing device defined to perform a wet substrate processing operation, wherein the substrate is moved sequentially through the first then second substrate processing devices.

31. The method for processing a substrate as recited in claim 30, wherein the dry substrate processing operation performed by the first substrate processing device serves to modify a cross-linked photoresist crust material present over a bulk photoresist material on the substrate such that the modified cross-linked photoresist crust material is removable through a wet substrate processing operation, and
wherein the wet substrate processing operation performed by the second substrate processing device serves to remove both the modified cross-linked photoresist crust material and the bulk photoresist material.
